(19) United States
(12) Patent Application Publication
(10) Pub. No.: US 2013/0101938 A1
(43) Pub. Date: Apr. 25, 2013

(54) ON-PRESS DEVELOPABLE LITHOGRAPHIC PRINTING PLATE PRECURSORS

(71) Applicants: Koji Hayashi, Tatebayashi (JP); Ruizheng Wang, Rochester, NY (US); Jianbing Huang, Norwalk, CT (US)

(72) Inventors: Koji Hayashi, Tatebayashi (JP); Ruizheng Wang, Rochester, NY (US); Jianbing Huang, Norwalk, CT (US)

(21) Appl. No.: 13/277,266

(22) Filed: Oct. 20, 2011

(51) Int. Cl. G03F 7/20; G03F 7/029; G03F 7/028

(52) U.S. Cl. 430/283.1; 430/281.1; 430/303; 430/302

(57) ABSTRACT

A negative-working lithographic printing plate precursor is designed for improved printout or contrast between exposed and non-exposed regions in its imageable layer. The imaged precursor can be developed on-press. The improvement in printout is achieved by using a combination of at least two infrared radiation absorbing cyanine dyes. At least one of these cyanine dyes comprises a methine chain substituent that comprises a group represented by Structure (I):

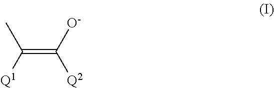

wherein Q¹ and Q² are hydrogen atoms or the same or different monovalent substituents, or Q¹ and Q² together provide carbon or heteroatoms to form a substituted or unsubstituted unsaturated ring. At least one other infrared radiation absorbing cyanine dyes does not comprise a group represented by Structure (I).

### FIELD OF THE INVENTION

This invention relates to negative-working, on-press developable lithographic printing plate precursors that exhibit improved printout characteristics. This invention also relates to a method of imaging and on-press developing such lithographic printing plate precursors.

### BACKGROUND OF THE INVENTION

In lithographic printing, ink receptive regions, known as image areas, are generated on a more hydrophilic surface in a lithographic print. When the lithographic printing plate surface is moistened with water and ink is applied, the more hydrophilic regions retain the water (fountain solution) and repel the ink the ink receptive regions accept the ink and repel the water. The ink is then transferred to the surface of suitable materials upon which the image is to be reproduced. In some instances, the ink can be first transferred to an intermediate blanket that in turn is used to transfer the ink to the surface of the materials upon which the image is to be reproduced.

Lithographic printing plate precursors useful to prepare lithographic (or offset) printing plates typically comprise one or more imageable layers applied over a hydrophilic surface of a substrate (or intermediate layers). The imageable layer(s) can comprise one or more radiation-sensitive components dispersed within a suitable binder. Following imaging, either the exposed regions or the non-exposed regions of the imageable layer(s) are removed by a suitable developer, revealing the underlying more hydrophilic surface of the substrate. If the exposed regions are removed, the element is considered as positive-working. Conversely, if the non-exposed regions are removed, the element is considered as negative-working. In each instance, the regions of the imageable layer(s) that remain are ink-receptive, and the regions of the more hydrophilic surface revealed by the developing process accept water or aqueous solutions (typically a fountain solution), and repel ink.

“Laser direct imaging” methods (LDI) are known that directly form an offset printing plate or printing circuit board using digital data from a computer, and provide numerous advantages over the previous processes using masking photographic films. There has been considerable development in this field from more efficient lasers, improved imageable compositions and components thereof.

Various radiation-sensitive compositions are known for use in negative-working lithographic printing plate precursors as described for example in U.S. Pat. No. 6,309,792 (Hauck et al.), U.S. Pat. No. 6,893,797 (Munnelly et al.), U.S. Pat. No. 6,727,281 (Tao et al.), U.S. Pat. No. 6,899,994 (Huang et al.), and U.S. Pat. No. 7,429,445 (Munnelly et al.), U.S. Patent Application Publications 2002/0168494 (Nagata et al.), 2003/0118939 (West et al.), and EP Publications 1,079,276A2 (Lifka et al.) and 1,449,650A2 (Goto et al.).

U.S. Pat. No. 7,429,445 (Munnelly et al.) describes on-press developable negative-working lithographic printing plate precursors that contain various infrared radiation absorbing dyes that have tetraaryl pentadiene chromophores, and nonionic phosphate acrylates to increase imaging sensitivity.

U.S. Patent Application Publication 2010/0075260 (Sasaki) describes a lithographic printing plate making method using a lithographic printing plate precursor having a compound that generates an acid light or heat, and the imaged precursor is developed on-press and has color contrast for inspection.

Lithographic printing plate precursors can contain a colorant (dye or pigment) in the radiation-sensitive composition (imageable layer) that has the function of making the image visible in order to be inspected and evaluated for plate positioning and bar code readability prior to pre-press calibration. Such colorants provide contrast between the image and the background. This image contrast (“printout”) is particularly needed for printing plate precursors designed for development on-press.

However, certain lithographic printing plate precursors cannot contain a colorant for different reasons. For example, the imaged lithographic printing plate precursors that are usually developed on-press have a colorless coating because if a colorant is present, it could contaminate the lithographic printing ink and the fountain solution used for development and printing, with the result of altering the printed color shades. However, sometimes it is necessary for such lithographic printing plate precursors to be used the same way as those developed off-press. In such instances, the image needs to be seen and evaluated with sufficient printout.

U.S. Pat. No. 6,451,491 (Dhillon et al.) describes the high loading of contrast-providing pigments into the imaging layer using specific poly(vinyl acetal) polymers and specific combinations of loading solvent mixtures. Such high amounts of pigments may not be suitable as they can destabilize imaging chemistry or developers used to remove non-imaged regions in negative-working lithographic printing plate precursors.

Other contrast-providing colorants are obtained from leuco dyes that become colored in the presence of an acid or thermal acid generator, as described for example, in U.S. Pat. No. 7,402,374 (Oohashi et al.), U.S. Pat. No. 7,425,406 (Oshima et al.) and U.S. Pat. No. 7,462,440 (Yamasaki). These imaging materials have disadvantages because the acid or radical forming mechanism can be triggered prematurely during the drying of the plate leading to unwanted color, especially in on-press developed lithographic printing plates.

Various negative-working imageable lithographic printing plate precursors have been designed for processing or development “on-press” using a fountain solution, lithographic printing ink, or both. For example, such elements are described in U.S. Patent Application Publication 2005-263021 (Mitsumoto et al.) and in U.S. Pat. No. 6,071,675 (Teng), U.S. Pat. No. 6,387,595 (Teng), U.S. Pat. No. 6,482,571 (Teng), U.S. Pat. No. 6,495,310 (Teng), U.S. Pat. No. 6,541,183 (Teng), U.S. Pat. No. 6,548,222 (Teng), U.S. Pat. No. 6,576,401 (Teng), U.S. Pat. No. 6,899,994 (Huang et al.), U.S. Pat. No. 6,902,866 (Teng), and U.S. Pat. No. 7,089,856 (Teng). U.S. Patent Application Publications 2005/0170282 (Inno et al.), 2005/0233251 (Kakino et al.), 2003/0068575 (Yanaka), 2006/0046189 (Kunita et al.), and 2007/0072119 (Iwai et al.), and EP Publications 1,614,541 (Callant et al.), 1,736,312 (Callant et al.), and 1,754,614 (Kakino et al.) describe lithographic printing plate precursors that contain a discoloring agent or system capable of generating a color change upon exposure for providing printout.

U.S. Patent Application Publication 2009/0047599 (Home et al.) describes the use of specific spirolactone or spirolactam leuco dye color formers in the imageable layer of negative-working lithographic printing plate precursors. U.S. Patent Application Publication 2007/0072119 (Iwai et al.) and EP 1,849,836 (Iwai et al.) describe the use of infrared radiation-sensitive cyanine dyes.

After imaging, lithographic printing plates can be inspected to make sure the desired image has been obtained. For lithographic printing plate precursors that are normally processed (or developed) off-press, this inspection can occur easily before mounting on the printing press. The plate manufacturer often adds a colorant to the imaging composition to facilitate this inspection of printout.

For imaged elements that are to be developed on-press, the image is not easily identified. Adding colorant to on-press developable imaging compositions compromises plate shelf life, on-press developability, or imaging sensitivity, and the colorant can color-contaminate printing press inks. Thus, there is a need for an adequate printout that provides visibility to the image on the printing plate before on-press development. Simply increasing imaging energy beyond that required for image durability will result in an increase in dot gain. So, the industry needs a different way to improve the printout without causing other problems.

U.S. Patent Application Publication 2009-0269699 (Munnelly et al.) describes the use of IR absorbable dyes to improve color contrast (printout) in on-press developable lithographic printing plate precursors.

U.S. Patent Application Publication 2010-0316956 (Memetea et al.) describes the application of a coloring fluid to the imaged precursor such that the optical density in the solid exposed regions is OD₂ that is greater than OD₁. This coloring fluid comprises a water-insoluble colorant and a solvent that is capable of swelling the solid exposed regions of the imageable layer.

U.S. Patent Application Publication 2010-0227269 (Simpson et al.) describes the use of a visible pigment and dye mixture for color contrast (printout).

U.S. Patent Application Publication 2010-0209846 (Strehmel et al.) describes the use of water-soluble visible contrast dyes.

Copending and commonly assigned U.S. Ser. No. 12/906,190 (filed Oct. 18, 2010 by Savariar-Hauck and Hauck) describes on-press developable lithographic printing plate precursors that comprise a first infrared radiation absorbing dye that has a tetraaryl pentadiene chromophore and a second infrared radiation absorbing dye that is different than the first infrared radiation absorbing compound. This combination of dyes is used to increase image contrast (printout) between the image of a lithographic printing plate and its background. These lithographic printing plate precursors have two different infrared radiation (IR) absorbing compounds, and one of them also absorbs in the visible region and thus provides the color contrast while the other infrared radiation absorbing compound provides the necessary sensitivity in the infrared radiation for image formation.

Despite all of these improvements to provide image contrast, there remains a need for improved contrast (printout) between the image and background of lithographic printing plates, while achieving high infrared imaging speed and good press life. While combinations of infrared radiation absorbers have been used for this purpose in some lithographic printing plate precursors, it is not certain what combinations of infrared radiation absorbers will provide these properties at the same time.

### SUMMARY OF THE INVENTION

This invention provides a negative-working, on-press developable lithographic printing plate precursor comprising a substrate, and having thereon an infrared radiation-sensitive imageable layer comprising:

a free radically polymerizable component,

an initiator composition that provides free radicals upon irradiation by infrared radiation,

a polymeric binder,

one or more first infrared radiation absorbing cyanine dyes, each having two of the same or different heterocyclic groups that are connected to each other by a methine chain having at least 7 carbon atoms, and the methine chain comprises a substituent that comprises at least one group represented by the following Structure (I):

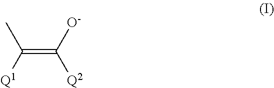

wherein Q¹ and Q² are hydrogen atoms or the same or different monovalent substituents, or Q¹ and Q² together provide carbon or heteroatoms to form a substituted or unsubstituted unsaturated ring, wherein the one or more first infrared radiation absorbing cyanine dyes are present in the infrared radiation-sensitive imageable layer in an amount of at least 2 weight %, based on the layer total solids, and

one or more second infrared radiation absorbing cyanine dyes that do not comprise a group represented by Structure (I).

In some preferred embodiments, the precursor is further defined wherein:

Structure (I) of the one or more first infrared radiation absorbing cyanine dyes can be further defined by Structure (Ia) or Structure (Ib):

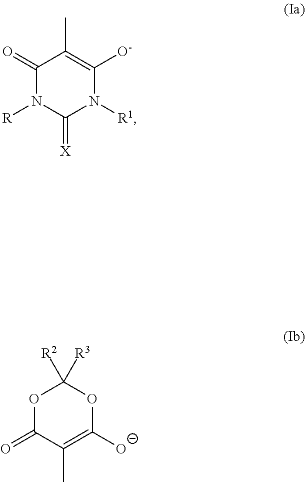

wherein X is an oxygen atom or sulfur atom, and R, R¹, R², and R³ are independently hydrogen, or substituted or unsubstituted alkyl, alkenyl, alkoxy, or phenyl groups,

the molar ratio of the first infrared radiation absorbing cyanine dye to the second infrared radiation absorbing cyanine dye is at least 5:1 and to 1:2,

the first and second infrared radiation absorbing cyanine dyes are present in the imageable layer independently in amounts of at least 2 weight % and up to and including 10 weight %,

at least one of the one or more second infrared radiation absorbing cyanine dyes comprises one or more carboxy, sulfo, or phosphor groups that are attached to one or more of the heterocyclic groups,

upon irradiation at a wavelength of at least 700 nm and up to and including 1400 nm, provides a color change in the imageable layer of at least 0.15 ΔOD compared to the imageable layer before such irradiation,

the initiator composition comprises a diaryliodonium tetraaryl borate, and

the polymeric binder is a graft copolymer comprising a hydrophobic backbone to which are attached side chains comprising polyalkylene oxide segments, or the polymeric binder comprises a hydrophobic backbone to which are attached side chains comprising ethylenically unsaturated polymerizable groups, or the polymeric binder comprises a hydrophobic backbone to which are attached both side chains comprising polyalkylene oxide segments and side chains comprising ethylenically unsaturated polymerizable groups.

This invention also provides a method for providing a lithographic printing plate, comprising:

imagewise exposing the negative-working, on-press developable lithographic printing plate precursor of this invention to infrared radiation to form exposed and non-exposed regions in the imaged imageable layer, and

without contacting it with an alkaline processing solution, mounting the imaged imageable layer onto a printing press and removing the non-exposed regions of the imaged imageable layer using a lithographic printing ink, fountain solution, or both lithographic printing ink and fountain solution.

This method can also be practiced with the preferred embodiments described above by:

imagewise exposing the preferred negative-working, on-press developable lithographic printing plate precursor to infrared radiation to form exposed and non-exposed regions in the imaged imageable layer, wherein the ΔOD between the exposed and non-exposed regions is at least 0.15, and

without contacting it with an alkaline processing solution, mounting the imaged imageable layer onto a printing press and removing the non-exposed regions of the imaged imageable layer using a lithographic printing ink, fountain solution, or both lithographic printing ink and fountain solution.

The present invention provides on-press developable lithographic printing plate precursors that exhibit high visible color contrast (printout) after imaging using infrared radiation. In addition, these precursors exhibit high imaging speed (sensitivity) and long press life (run length).

These advantages were unexpected achieved by using a unique combination of at least two types of infrared radiation (IR) absorbing cyanine dyes as defined herein. One of those IR absorbing cyanine dyes has a group identified herein by Structure (I) in the methine chain connecting two chromophoric heterocyclic moieties while another of the IR absorbing cyanine dyes does not have a group represented by Structure (I).

### DETAILED DESCRIPTION OF THE INVENTION

### Definitions

Unless the context indicates otherwise, when used herein, the terms “on-press developable lithographic printing plate precursor”, “lithographic printing plate precursor”, “printing plate precursor”, and “precursor” are meant to be references to embodiments of the present invention.

In addition, unless the context indicates otherwise, the various components described herein such as “first infrared radiation absorber”, “second infrared radiation absorber”, “initiator”, “co-initiator”, “free radically polymerizable component”, “polymeric binder”, and similar terms also refer to mixtures of such components.

As used herein to define various components of the radiation-sensitive compositions, imageable layers, lithographic printing plate precursors, formulations, and layers, unless otherwise indicated, the singular forms “a”, “an”, and “the” are intended to include one or more of the components (that is, including plurality referents).

Each term that is not explicitly defined in the present application is to be understood to have a meaning that is commonly accepted by those skilled in the art. If the construction of a term would render it meaningless or essentially meaningless in its context, the term's definition should be taken from a standard dictionary.

Moreover, unless otherwise indicated, percentages refer to percents by total dry weight, for example, weight % based on total solids of either an imageable layer or radiation-sensitive composition. Unless otherwise indicated, the percentages can be the same for either the dry imageable layer or the total solids of radiation-sensitive composition.

For clarification of definitions for any terms relating to polymers, reference should be made to “Glossary of Basic Terms in Polymer Science” as published by the International Union of Pure and Applied Chemistry (“IUPAC”), Pure Appl. Chem. 68, 2287-2311 (1996). However, any definitions explicitly set forth herein should be regarded as controlling.

The term “polymer” refers to high and low molecular weight polymers including oligomers and includes homopolymers and copolymers.

The term “copolymer” refers to polymers that are derived from two or more different monomers.

The term “backbone” refers to the chain of atoms (carbon or heteroatoms) in a polymer to which a plurality of pendant groups are attached. One example of such a backbone is an “all carbon” backbone obtained from the polymerization of one or more ethylenically unsaturated polymerizable monomers. However, other backbones can include heteroatoms wherein the polymer is formed by a condensation reaction or some other means.

As used herein, a “stack” of lithographic printing plate precursors includes two or more of the precursors. Interleaf paper can be present between adjacent precursors, or it can be absent from the stack. Generally, a stack has at least two and more typically at least 10 and up to and including 1500 lithographic printing plate precursors, or at least 100 of them, or at least 250 and up to and including 800 of the lithographic printing plate precursors.

The term “OD₁” refers to the optical density of the non-imaged surface of the lithographic printing plate precursor, as measured using a spectrodensitometer. This value is an average of spectrodensitometer readings taken over several solid patches distributed over the precursor surface. Each of the solid patches should be large enough for proper spectrodensitometer readings according to the operating instructions for the particular instrument being used. For example, optical density (OD) can be determined using an X-Rite 500 spectrodensitometer (X-Rite, Inc. Grand Rapids, Mich.).

The term “OD₂” refers to the optical density of the solid exposed regions of the lithographic printing plate precursor. This value is also determined as an average over several solid image regions using the same spectrodensitometer (and filters) used for determined OD₁.

The difference between OD₂ and OD₁ is ΔOD and is generally at least 0.1 and typically at least 0.15 in the practice of this invention.

### Substrates

The substrate used to prepare the lithographic printing plate precursors of this invention comprises a support that can be composed of any material that is conventionally used to prepare lithographic printing plates. It is usually in the form of a sheet, film, or foil (or web), and is strong, stable, and flexible and resistant to dimensional change under conditions of use so that color records will register a full-color image. Typically, the support can be any self-supporting material including polymeric films (such as polyester, polyethylene, polycarbonate, cellulose ester polymer, and polystyrene films), glass, ceramics, metal sheets or foils, or stiff papers (including resin-coated and metallized papers), or a lamination of any of these materials (such as a lamination of an aluminum foil onto a polyester film). Metal supports include sheets or foils of aluminum, copper, zinc, titanium, and alloys thereof.

One useful substrate is composed of an aluminum support that can be treated using techniques known in the art, including roughening of some type by physical (mechanical) graining, electrochemical graining, or chemical graining, usually followed by acid anodizing. The aluminum support can be roughened by physical or electrochemical graining and then anodized using phosphoric or sulfuric acid and conventional procedures. A useful hydrophilic lithographic substrate is an electrochemically grained and sulfuric acid or phosphoric acid anodized aluminum support that provides a hydrophilic surface for lithographic printing.

Sulfuric acid anodization of the aluminum support generally provides an oxide weight (coverage) on the surface of at least 1.5 and up to and including 5 g/m². Phosphoric acid anodization generally provides an oxide weight on the surface of at least 1 and up to and including 5 g/m². When sulfuric acid is used for anodization, higher oxide weight (at least 3 g/m²) can provide longer press life.

The aluminum support can also be treated with, for example, sodium silicate, dextrin, calcium zirconium fluoride, hexafluorosilicic acid, poly(vinyl phosphonic acid) (PVPA), vinyl phosphonic acid copolymer, poly[(meth)acrylic acid], or acrylic acid copolymer to increase hydrophilicity. Still further, the aluminum support can be treated with a phosphate solution that can further contain an inorganic fluoride (PF).

The thickness of the substrate can be varied but should be sufficient to sustain the wear from printing and thin enough to wrap around a printing form. Useful embodiments include a treated aluminum foil having a thickness of at least 100 μm and up to and including 700 μm.

### Negative-Working Lithographic Printing Plate Precursors

The precursors are negative-working, and can be formed by suitable application of a radiation-sensitive composition as described below to a suitable substrate (described above) to form an imageable layer. This substrate can be treated or coated in various ways as described above prior to application of the radiation-sensitive composition to improve hydrophilicity. There is only a single imageable layer comprising the radiation-sensitive composition and it is usually the outermost layer in the precursor. Thus, in most embodiments, no oxygen barrier or outermost protective topcoat is present in the lithographic printing plate precursors.

Useful details of negative-working lithographic printing plate precursors are described for example, in EP Patent Publications 770,494A1 (Vermeersch et al.), 924,570A1 (Fujimaki et al.), 1,063,103A1 (Uesugi), EP 1,182,033A1 (Fujimako et al.), EP 1,342,568A1 (Vermeersch et al.), EP 1,449,650A1 (Goto), and EP 1,614,539A1 (Vermeersch et al.), U.S. Pat. No. 4,511,645 (Koike et al.), U.S. Pat. No. 6,027,857 (Teng), U.S. Pat. No. 6,309,792 (Hauck et al.), U.S. Pat. No. 6,569,603 (Furukawa et al.), U.S. Pat. No. 6,899,994 (Huang et al.), U.S. Pat. No. 7,045,271 (Tao et al.), U.S. Pat. No. 7,049,046 (Tao et al.), U.S. Pat. No. 7,261,998 (Hayashi et al.), U.S. Pat. No. 7,279,255 (Tao et al.), U.S. Pat. No. 7,285,372 (Baumann et al.), U.S. Pat. No. 7,291,438 (Sakurai et al.), U.S. Pat. No. 7,326,521 (Tao et al.), U.S. Pat. No. 7,332,253 (Tao et al.), U.S. Pat. No. 7,442,486 (Baumann et al.), U.S. Pat. No. 7,452,638 (Yu et al.), U.S. Pat. No. 7,524,614 (Tao et al.), U.S. Pat. No. 7,560,221 (Timpe et al.), U.S. Pat. No. 7,574,959 (Baumann et al.), U.S. Pat. No. 7,615,323 (Shrehmel et al.), and U.S. Pat. No. 7,672,241 (Munnelly et al.), and U.S. Patent Application Publications 2003/0064318 (Huang et al.), 2004/0265736 (Aoshima et al.), 2005/0266349 (Van Damme et al.), and 2006/0019200 (Vermeersch et al.). Other negative-working compositions and elements are described for example in U.S. Pat. No. 6,232,038 (Takasaki), U.S. Pat. No. 6,627,380 (Saito et al.), U.S. Pat. No. 6,514,657 (Sakurai et al.), U.S. Pat. No. 6,808,857 (Miyamoto et al.), and U.S. Patent Publication 2009/0092923 (Hayashi).

The radiation-sensitive compositions and imageable layers used in such precursors generally include one or more polymeric binders that facilitate the on-press developability of the imaged precursors. Such polymeric binders include but are not limited to, those that are not generally crosslinkable and are usually present at least partially as discrete particles (not-agglomerated). Such polymers can be present as discrete particles having an average particle size of at least 10 nm and up to and including 500 nm, and typically at least 100 nm and up to and including 450 nm, and that are generally distributed uniformly within that layer. The particulate polymeric binders exist at room temperature as discrete particles, for example in an aqueous dispersion. Such polymeric binders generally have a molecular weight (Mₙ) of at least 5,000 and typically at least 20,000 and up to and including 100,000, or at least 30,000 and up to and including 80,000, as determined by Gel Permeation Chromatography.

Useful particulate polymeric binders generally include polymeric emulsions or dispersions of polymers having hydrophobic backbones to which are directly or indirectly linked pendant poly(alkylene oxide) segments (for example at least 10 alkylene glycol segments or units), cyano groups, or both, that are described for example in U.S. Pat. No. 6,582,882 (Pappas et al.), U.S. Pat. No. 6,899,994 (Huang et al.), U.S. Pat. No. 7,005,234 (Hoshi et al.), and U.S. Pat. No. 7,368,215 (Munnelly et al.) and US Patent Application Publication 2005/0003285 (Hayashi et al.). More specifically, such polymeric binders include but are not limited to, graft copolymers having both hydrophobic and hydrophilic segments, block and graft copolymers having polyethylene oxide (PEO) segments, polymers having both pendant poly(alkylene oxide) segments and cyano groups, in random fashion, attached to the polymer backbone, and various hydrophilic polymeric binders that can have various hydrophilic groups such as hydroxyl, carboxy, hydroxyethyl, hydroxypropyl, amino, aminoethyl, aminopropyl, carboxymethyl, sulfono, or other groups readily apparent to a worker skilled in the art.

Alternatively, the particulate polymeric binders can also have a backbone comprising multiple (at least two) urethane moieties. Such polymeric binders generally have a molecular weight (Mₙ) of at least 2,000 and typically at least 100,000 and up to and including 500,000, or at least 100,000 and up to and including 300,000, as determined by dynamic light scattering.

Additional useful polymeric binders are particulate poly(urethane-acrylic) hybrids that are distributed (usually uniformly) throughout the imageable layer. Each of these hybrids has a molecular weight of at least 50,000 and up to and including 500,000 and the particles have an average particle size of at least 10 nm and up to and including 10,000 nm (typically at least 30 nm and up to and including 500 nm or at least 30 nm and up to and including 150 nm). These hybrids can be either “aromatic” or “aliphatic” in nature depending upon the specific reactants used in their manufacture. Blends of particles of two or more poly(urethane-acrylic) hybrids can also be used. Some poly(urethane-acrylic) hybrids are commercially available in dispersions from Air Products and Chemicals, Inc. (Allentown, Pa.), for example, as the Hybridur® 540, 560, 570, 580, 870, 878, 880 polymer dispersions of poly(urethane-acrylic) hybrid particles. These dispersions generally include at least 30% solids of the poly(urethane-acrylic) hybrid particles in a suitable aqueous medium that can also include commercial surfactants, anti-foaming agents, dispersing agents, anti-corrosive agents, and optionally pigments and water-miscible organic solvents.

These polymeric binders are generally present in the imageable layer in an amount of at least 5 weight % and up to and including 70 weight % of the radiation-sensitive composition.

The radiation-sensitive composition can include a secondary polymeric binder that can be homogenous, that is, non-particulate or dissolved in the coating solvent, or they can exist as discrete particles. Such secondary polymeric binders include but are not limited to, (meth)acrylic acid and acid ester resins [such as (meth)acrylates], polyvinyl acetals, phenolic resins, polymers derived from styrene, N-substituted cyclic imides or maleic anhydrides, such as those described in EP 1,182,033A1 (Fujimaki et al.) and U.S. Pat. No. 6,309,792 (Hauck et al.), U.S. Pat. No. 6,352,812 (Shimazu et al.), U.S. Pat. No. 6,569,603 (Furukawa et al.), and U.S. Pat. No. 6,893,797 (Munnelly et al.). Also useful are the vinyl carbazole polymers described in U.S. Pat. No. 7,175,949 (Tao et al.), and the polymers having pendant vinyl groups as described in U.S. Pat. No. 7,279,255 (Tao et al.), both patents incorporated herein by reference. Random copolymers of polyethylene glycol methacrylate/acrylonitrile/styrene in particulate form, dissolved random copolymers derived from carboxyphenyl methacrylamide/acrylonitrile/methacrylamide/N-phenyl maleimide, random copolymers derived from polyethylene glycol methacrylate/acrylonitrile/vinyl carbazole/styrene/methacrylic acid, random copolymers derived from N-phenyl maleimide/methacrylamide/methacrylic acid, random copolymers derived from urethane-acrylic intermediate A (the reaction product of p-toluene sulfonyl isocyanate and hydroxyl ethyl methacrylate)/acrylonitrile/N-phenyl maleimide, and random copolymers derived from N-methoxymethyl methacrylamide/methacrylic acid/acrylonitrile/n-phenylmaleimide are useful.

The radiation-sensitive composition (and imageable layer) includes one or more free radically polymerizable components, each of which contains one or more free radically polymerizable groups that can be polymerized using free radical initiation. For example, such free radically polymerizable components can contain one or more free radical polymerizable monomers or oligomers having one or more addition polymerizable ethylenically unsaturated groups, crosslinkable ethylenically unsaturated groups, ring-opening polymerizable groups, azido groups, aryldiazonium salt groups, aryldiazosulfonate groups, or a combination thereof. Similarly, crosslinkable polymers having such free radically polymerizable groups can also be used. Oligomers or prepolymers, such as urethane acrylates and methacrylates, epoxide acrylates and methacrylates, polyester acrylates and methacrylates, polyether acrylates and methacrylates, and unsaturated polyester resins can be used. In some embodiments, the free radically polymerizable component comprises carboxyl groups.

Free radically polymerizable compounds include those derived from urea urethane (meth)acrylates or urethane (meth)acrylates having multiple polymerizable groups. For example, a free radically polymerizable component can be prepared by reacting DESMODUR® N100 aliphatic polyisocyanate resin based on hexamethylene diisocyanate (Bayer Corp., Milford, Conn.) with hydroxyethyl acrylate and pentaerythritol triacrylate. Useful free radically polymerizable compounds include NK Ester A-DPH (dipentaerythritol hexaacrylate) that is available from Kowa American, and Sartomer 399 (dipentaerythritol pentaacrylate), Sartomer 355 (di-trimethylolpropane tetraacrylate), Sartomer 295 (pentaerythritol tetraacrylate), and Sartomer 415 [ethoxylated (20)trimethylolpropane triacrylate] that are available from Sartomer Company, Inc.

Numerous other free radically polymerizable components are known to those skilled in the art and are described in considerable literature including Photoreactive Polymers: The Science and Technology of Resists, A Reiser, Wiley, New York, 1989, pp. 102-177, by B. M. Monroe in Radiation Curing: Science and Technology, S. P. Pappas, Ed., Plenum, New York, 1992, pp. 399-440, and in “Polymer Imaging” by A. B. Cohen and P. Walker, in Imaging Processes and Material, J. M. Sturge et al. (Eds.), Van Nostrand Reinhold, New York, 1989, pp. 226-262. For example, useful free radically polymerizable components are also described in EP 1,182,033A1 (Fujimaki et al.), beginning with paragraph [0170], and in U.S. Pat. No. 6,309,792 (Hauck et al.), U.S. Pat. No. 6,569,603 (Furukawa), and U.S. Pat. No. 6,893,797 (Munnelly et al.). Other useful free radically polymerizable components include those described in U.S. Patent Application Publication 2009/0142695 (noted above) that include 1H-tetrazole groups.

In addition to, or in place of the free radically polymerizable components described above, the radiation-sensitive composition can include polymeric materials that include side chains attached to the backbone, which side chains include one or more free radically polymerizable groups (such as ethylenically unsaturated groups) that can be polymerized (crosslinked) in response to free radicals produced by the initiator composition (described below). There can be at least two of these side chains per molecule. The free radically polymerizable groups (or ethylenically unsaturated groups) can be part of aliphatic or aromatic acrylate side chains attached to the polymeric backbone. Generally, there are at least 2 and up to and including 20 such groups per molecule.

The one or more free radically polymerizable components are generally present in the radiation-sensitive composition (imageable layer) in an amount of at least 10 weight % and up to and including 70 weight %.

Such free radically polymerizable polymers can also comprise hydrophilic groups including but not limited to, carboxy, sulfo, or phospho groups, either attached directly to the backbone or attached as part of side chains other than the free radically polymerizable side chains.

This radiation-sensitive composition also includes an initiator composition that includes one or more initiators (and possibly, co-initiators) that are capable of generating free radicals sufficient to initiate polymerization of all the various free radically polymerizable components upon exposure of the composition to imaging infrared radiation. The initiator composition is responsive, for example, to electromagnetic radiation in the infrared spectral regions, corresponding to the broad spectral range of at least 700 nm and up to and including 1400 nm, and typically radiation of at least 700 nm and up to and including 1250 nm.

More typically, the initiator composition includes one or more an electron acceptors and one or more co-initiators that are capable of donating electrons, hydrogen atoms, or a hydrocarbon radical.

In general, suitable initiator compositions for IR-radiation sensitive compositions comprise initiators that include but are not limited to, aromatic sulfonylhalides, trihalogenomethylsulfones, imides (such as N-benzoyloxyphthalimide), diazosulfonates, 9,10-dihydroanthracene derivatives, N-aryl, S-aryl, or O-aryl polycarboxylic acids with at least 2 carboxy groups of which at least one is bonded to the nitrogen, oxygen, or sulfur atom of the aryl moiety (such as aniline diacetic acid and derivatives thereof and other “co-initiators” described in U.S. Pat. No. 5,629,354 of West et al.), oxime ethers and oxime esters (such as those derived from benzoin), α-hydroxy or α-amino-acetophenones, trihalogenomethyl-arylsulfones, benzoin ethers and esters, peroxides (such as benzoyl peroxide), hydroperoxides (such as cumyl hydroperoxide), azo compounds (such as azo bis-isobutyronitrile), 2,4,5-triarylimidazolyl dimers (also known as hexaarylbiimidazoles, or “HABI's”) as described for example in U.S. Pat. No. 4,565,769 (Dueber et al.), trihalomethyl substituted triazines, boron-containing compounds (such as tetraarylborates and alkyltriarylborates) and organoborate salts such as those described in U.S. Pat. No. 6,562,543 (Ogata et al.), and onium salts (such as ammonium salts, diaryliodonium salts, triarylsulfonium salts, aryldiazonium salts, and N-alkoxypyridinium salts).

Useful initiator compositions for IR radiation sensitive compositions include onium compounds including ammonium, sulfonium, iodonium, and phosphonium compounds. Useful iodonium cations are well known in the art including but not limited to, U.S. Patent Application Publication 2002/0068241 (Oohashi et al.), WO 2004/101280 (Munnelly et al.), and U.S. Pat. No. 5,086,086 (Brown-Wensley et al.), U.S. Pat. No. 5,965,319 (Kobayashi), and U.S. Pat. No. 6,051,366 (Baumann et al.). For example, a useful iodonium cation includes a positively charged iodonium, (4-methylphenyl)[4-(2-methylpropyl)phenyl]-moiety and a suitable negatively charged counterion.

Thus, the iodonium cations can be supplied as part of one or more iodonium salts, and the iodonium cations can be supplied as iodonium borates also containing suitable boron-containing anions. For example, the iodonium cations and the boron-containing anions can be supplied as part of substituted or unsubstituted diaryliodonium salts that are combinations of Structures (I) and (II) described in Cols. 6-8 of U.S. Pat. No. 7,524,614 (Tao et al.). Polyiodonium compounds with multiple boron-containing anions can also be used as described in U.S. Pat. No. 7,862,984 (Hayashi et al.).

Useful IR radiation-sensitive initiator compositions can comprise one or more diaryliodonium borate compounds such as diaryliodonium tetraarylborates. Representative iodonium borate compounds useful in this invention include but are not limited to, 4-octyloxyphenyl phenyliodonium tetraphenylborate, [4-[(2-hydroxytetradecyl)-oxy]phenyl]phenyliodonium tetraphenylborate, bis(4-t-butylphenyl)iodonium tetraphenylborate, 4-methylphenyl-4′-hexylphenyliodonium tetraphenylborate, 4-methylphenyl-4′-cyclohexylphenyliodonium tetraphenylborate, bis(t-butylphenyl)iodonium tetrakis(pentafluorophenyl)borate, 4-hexylphenyl-phenyliodonium tetraphenylborate, 4-methylphenyl-4′-cyclohexyl-phenyliodonium n-butyltriphenylborate, 4-cyclohexylphenyl-phenyliodonium tetraphenylborate, 2-methyl-4-t-butylphenyl-4′-methylphenyliodonium tetraphenylborate, 4-methylphenyl-4′-pentylphenyliodonium tetrakis[3,5-bis(trifluoromethyl)phenyl]borate, 4-methoxyphenyl-4′-cyclohexyl-phenyliodonium tetrakis(penta-fluorophenyl)borate, 4-methylphenyl-4′-dodecylphenyliodonium tetrakis(4-fluorophenyl)borate, bis(dodecylphenyl)-iodonium tetrakis(pentafluorophenyl)-borate, and bis(4-t-butylphenyl)iodonium tetrakis(1-imidazolyl)borate. Useful compounds include bis(4-t-butylphenyl)-iodonium tetraphenylborate, 4-methylphenyl-4′-hexylphenyliodonium tetraphenylborate, 2-methyl-4-t-butylphenyl-4′-methylphenyliodonium tetraphenylborate, and 4-methylphenyl-4′-cyclohexylphenyliodonium tetraphenylborate. Mixtures of two or more of these compounds can also be used in the initiator composition.

The one or more initiators (and co-initiators) can be present in the radiation-sensitive composition (imageable layer) in an amount of at least 1 weight % and up to and including 20 weight %.

The imageable layers comprise a radiation-sensitive imaging composition that includes first and second infrared radiation absorbing cyanine dyes. Each of these cyanine dyes has the same or different heterocyclic groups that are connected to each other by a methine chain having at least 7 carbon atoms. This methine chain can be substituted with one or more substituents and at least one of these substituents comprises at least one group represented by Structure (I) below. The methine chain can be a straight chain or comprise unsaturated cyclic groups long its length.

Generally, the first cyanine dye has the same or different heterocyclic groups at the ends of the methine chain, and thus has sufficient heteroatoms such as oxygen, nitrogen, and sulfur atoms, along with carbon atoms, to form the desired heterocyclic rings that include but are not limited to, quinoline, indole, benzothiazole, iminocyclodexadiene, pyrylium, thiapyrylium, squalium, croconium, and azulenium groups. The quinolinium groups and benzothiazole groups are particularly useful. Some representative basic cyanine dye structures are shown in Columns 6-9 of U.S. Pat. No. 6,153,356 (Urano et al.) that is incorporated herein.

More particularly, the first infrared radiation absorbing cyanine dye comprises a methine chain that has a substituent that comprises at least one group represented by the following Structure (I):

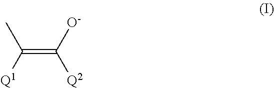

wherein Q¹ and Q² are independently hydrogen atoms or the same or different monovalent substituents, or Q¹ and Q² together provide sufficient carbon or heteroatoms to form a substituted or unsubstituted unsaturated ring. For example, each of Q¹ and Q² can be a hydrocarbon group including an alkyl group having 1 to 10 carbon atoms or an aryl group having 6 or 10 carbon atoms in the aromatic ring, which hydrocarbon group can be substituted with an amino, (thio)ether, (thio)carbonyl), cyano, (thio)acyl, alkoxycarbonyl, (thio)amide, or imino group. The term “(thio)ether” means an ether group or a thioether group, and other groups are similarly defined.

For example, Q¹ is particularly an electron withdrawing (attracting) group such as a substituted or unsubstituted carbonyl, (thio)acyl, alkoxycarbonyl, or (thio)amide. Q² is particularly an electron donating group such as a substituted or unsubstituted amino or (thio)ether group. Q¹ and Q² can be connected directly by a single or double bond, or via a connecting group.

Particularly useful substituents for the methine chain comprise the following groups (α-1) through (α-7) that comprise a group defined by Structure (I):

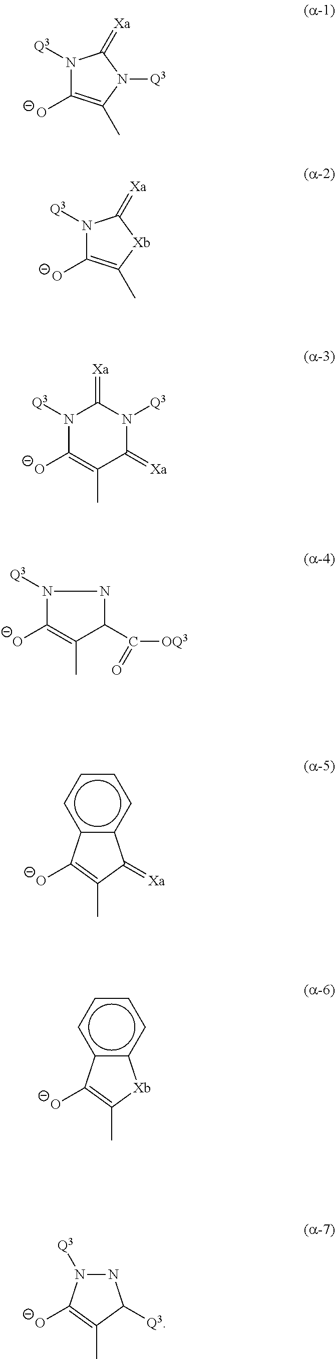

In these formulae, each of Xₐ and X_{b} independently represent sulfur or oxygen atoms, Q³ is a substituted or unsubstituted alkyl group, substituted or unsubstituted alkenyl group, substituted or unsubstituted alkoxy group, or a substituted or unsubstituted aryl group. When multiple Q³ groups are present, they can be the same or different groups. The (α-3) groups are particularly useful, having a barbituric acid or thiobarbituric acid structure, particularly when Q³ is a substituted or unsubstituted alkyl group having 1 to 10 carbon atoms or a substituted or unsubstituted phenyl or naphthyl group. Particularly useful examples of such groups are shown in Structures (Ia) and (Ib) below:

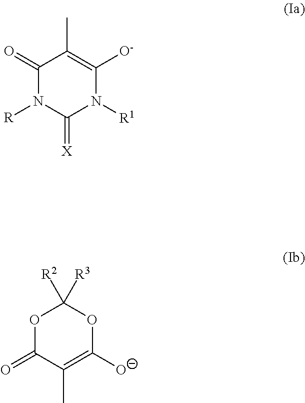

wherein X is an oxygen atom or sulfur atom, and R, R¹, R², and R³ are independently hydrogen, or substituted or unsubstituted alkyl groups having 1 to 10 carbon atoms, substituted or unsubstituted alkenyl groups having 2 to 10 carbon atoms, substituted or unsubstituted alkoxy groups having 1 to 10 carbon atoms, or a substituted or unsubstituted phenyl groups.

The useful first infrared radiation absorbing cyanine dyes generally have a cationic chromophore and sufficient anion counterions to provide a neutral charge for the molecule. Useful cations are well known in the art and include for example tetraaryl borates such as tetraphenyl borates as described for example in U.S. Pat. No. 7,524,614 (noted above).

Useful first infrared radiation absorbing cyanine dyes can be prepared using known methods using known starting materials and conditions as described in Col. 23 of U.S. Pat. No. 6,153,356 (noted above). Some of the compounds are available from commercial sources.

The radiation-sensitive composition (imaging layer) used in this invention includes one or more second infrared radiation absorbing cyanine dyes that can be similar to the first infrared radiation absorbing cyanine dyes except that they do not contain a group represented by Structure (I).

Thus, the second infrared radiation (IR) absorbing compound can be any known IR absorbing compound as long as it is different than the first infrared radiation absorbing cyanine dye as noted above. The second infrared radiation absorbing compounds are sensitive to infrared radiation (typically λₘₐₓ of at least 700 nm and up to and including 1400 nm) but are not particularly sensitive to visible radiation (typically of at least 450 nm and up to and including 700 nm). For example, useful second IR absorbing cyanine dyes include but are not limited to, azo dyes, squarilium dyes, croconate dyes, triarylamine dyes, thioazolium dyes, indolium dyes, oxonol dyes, oxaxolium dyes, cyanine dyes, merocyanine dyes, phthalocyanine dyes, indocyanine dyes, indotricarbocyanine dyes, oxatricarbocyanine dyes, thiocyanine dyes, thiatricarbocyanine dyes, cryptocyanine dyes, naphthalocyanine dyes, polyaniline dyes, polypyrrole dyes, polythiophene dyes, chalcogenopyryloarylidene and bi(chalcogenopyrylo)polymethine dyes, oxyindolizine dyes, pyrylium dyes, pyrazoline azo dyes, oxazine dyes, naphthoquinone dyes, anthraquinone dyes, quinoneimine dyes, methine dyes, arylmethine dyes, squarine dyes, oxazole dyes, croconine dyes, porphyrin dyes, and any substituted or ionic form of the preceding dye classes. Suitable dyes are also described in U.S. Pat. No. 5,208,135 (Patel et al.), U.S. Pat. No. 6,153,356 (Urano et al.), U.S. Pat. No. 6,264,920 (Achilefu et al.), U.S. Pat. No. 6,309,792 (Hauck et al.), U.S. Pat. No. 6,569,603 (noted above), U.S. Pat. No. 6,787,281 (Tao et al.), U.S. Pat. No. 7,135,271 (Kawaushi et al.), and EP 1,182,033A2 (noted above). Infrared radiation absorbing N-alkylsulfate cyanine dyes are described for example in U.S. Pat. No. 7,018,775 (Tao). A general description of one class of suitable cyanine dyes is shown by the formula in paragraph [0026] of WO 2004/101280 (Munnelly et al.). Some useful second infrared radiation absorbing cyanine dyes comprise one or more water-solubilizing groups such as sulfo, phosphor, and carboxy groups that can be attached to one or more of the heterocyclic groups.

In addition to low molecular weight IR-absorbing dyes having IR dye chromophores bonded to polymers can be used as well. Moreover, IR dye cations can be used as well, that is, the cation is the IR absorbing portion of the dye salt that ionically interacts with a polymer comprising carboxy, sulfo, phospho, or phosphono groups in the side chains.

Near infrared absorbing cyanine dyes are also useful and are described for example in U.S. Pat. No. 6,309,792 (noted above), U.S. Pat. No. 6,264,920 (Achilefu et al.), U.S. Pat. No. 6,153,356 (noted above), and U.S. Pat. No. 5,496,903 (Watanabe et al.). Suitable dyes can be formed using conventional methods and starting materials or obtained from various commercial sources. Other useful dyes for near infrared diode laser beams are described in U.S. Pat. No. 4,973,572 (DeBoer).

The amount of the one or more first infrared radiation absorbing cyanine dyes in the imageable layer is generally equal to or less than the amount of the one or more second infrared radiation absorbing cyanine dyes. For example, the molar ratio of the one or more first infrared radiation absorbing cyanine dyes to the one or more second infrared radiation absorbing cyanine dyes is from 5:1 and to and including 1:2, or more likely from 3:1 and to and including 1:1.

The one or more first infrared radiation absorbing cyanine dyes are present in the imageable layer in an amount of at least 2 weight % and typically in an amount of at least 2 weight % and up to and including 10 weight %. The one or more second infrared radiation absorbing dyes are present in an amount of at least 0.5 weight % and typically in an amount of at least 2 weight % and up to and including 10 weight %.

Useful IR-radiation sensitive compositions are described, for example, in the following patent, publications, and copending patent applications:

U.S. Pat. No. 7,452,638 (Yu et al.),

U.S. Patent Application Publication 2008/0254387 (Yu et al.),

U.S. Patent Application Publication 2008/0311520 (Yu et al.),

U.S. Patent Application Publication 2009/0263746 (Ray et al.), and

U.S. Patent Application Publication 2010/0021844 (Yu et al.).

The imageable layer can also include a “primary additive” that is a poly(alkylene glycol) or an ether or ester thereof that has a molecular weight of at least 200 and up to and including 4000. Useful primary additives include, but are not limited to, one or more of polyethylene glycol, polypropylene glycol, polyethylene glycol methyl ether, polyethylene glycol dimethyl ether, polyethylene glycol monoethyl ether, polyethylene glycol diacrylate, ethoxylated bisphenol A di(meth)acrylate, and polyethylene glycol mono methacrylate.

The imageable layer can further include a “secondary additive” that is a poly(vinyl alcohol), a poly(vinyl pyrrolidone), poly(vinyl imidazole), or polyester in an amount of up to and including 20 weight % based on the total dry weight of the imageable layer.

Additional additives in the imageable layer include color developers or acidic compounds such as monomeric phenolic compounds, organic acids or metal salts thereof, oxybenzoic acid esters, acid clays, and other compounds described for example in U.S. Patent Application Publication 2005/0170282 (Inno et al.). The imageable layer can also include a variety of optional compounds including but not limited to, dispersing agents, humectants, biocides, plasticizers, surfactants for coatability or other properties, viscosity builders, pH adjusters, drying agents, defoamers, preservatives, antioxidants, development aids, rheology modifiers or combinations thereof, or any other addenda commonly used in the lithographic art, in conventional amounts.

The radiation-sensitive composition and imageable layer can also contain a phosphate (meth)acrylate having a molecular weight generally greater than 250 as described in U.S. Pat. No. 7,429,445 (Munnelly et al.). By “phosphate (meth)acrylate” we also mean “phosphate methacrylates” and other derivatives having substituents on the vinyl group in the acrylate moiety.

The radiation-sensitive composition can be applied to the substrate as a solution or dispersion in a coating liquid using any suitable equipment and procedure, such as spin coating, knife coating, gravure coating, die coating, slot coating, bar coating, wire rod coating, roller coating, or extrusion hopper coating. The composition can also be applied by spraying onto a suitable support (such as an on-press printing cylinder). Typically, the radiation-sensitive composition is applied and dried to form an outermost layer of the precursor.

Illustrative of such manufacturing methods is mixing the various components needed for a specific imaging chemistry in a suitable organic solvent or mixtures thereof [such as methyl ethyl ketone (2-butanone), methanol, ethanol, 1-methoxy-2-propanol, iso-propyl alcohol, acetone, γ-butyrolactone, n-propanol, tetrahydrofuran, and others readily known in the art, as well as mixtures thereof], applying the resulting solution to a substrate, and removing the solvent(s) by evaporation under suitable drying conditions. Some representative coating solvents and imageable layer formulations are described in the Invention Examples below. After proper drying, the coating weight of the imageable layer is generally at least 0.1 g/m² and up to and including 5 g/m² or at least 0.5 g/m² and up to and including 3.5 g/m².

Layers can also be present under the imageable layer to enhance developability or to act as a thermal insulating layer.

The lithographic printing plate precursor generally does not include a water-soluble or water-dispersible outermost protective overcoat (also sometimes known as an “oxygen impermeable topcoat” or “oxygen barrier layer”) disposed over the imageable or radiation-sensitive layer, for example coated directly on the imageable layer.

But, when such an overcoat is present, it can be a water-soluble or water-dispersible overcoat (also sometimes known as an “oxygen impermeable topcoat” or “oxygen barrier layer”) disposed over the imageable layer. Such overcoat layers can comprise one or more water-soluble poly(vinyl alcohol)s having a saponification degree of at least 90% and generally have a dry coating weight of at least 0.1 and up to and including 2 g/m² in which the water-soluble poly(vinyl alcohol)s comprise at least 60% and up to and including 99% of the dry overcoat layer weight.

The overcoat can further comprise a second water-soluble polymer that is not a poly(vinyl alcohol) in an amount of from about 2 to about 38 weight %, and such second water-soluble polymer can be a poly(vinyl pyrrolidone), poly(ethyleneimine), poly(vinyl imidazole), poly(vinyl caprolactone), or a random copolymer derived from two or more of vinyl pyrrolidone, ethyleneimine, vinyl caprolactone, and vinyl imidazole, and vinyl acetamide.

Alternatively, the overcoat can be formed predominantly using one or more of polymeric binders such as poly(vinyl pyrrolidone), poly(ethyleneimine), poly(vinyl imidazole), and random copolymers from two or more of vinyl pyrrolidone, ethyleneimine and vinyl imidazole, and mixtures of such polymers. The formulations can also include cationic, anionic, and non-ionic wetting agents or surfactants, flow improvers or thickeners, antifoamants, colorants, particles such as aluminum oxide and silicon dioxide, and biocides. Details about such addenda are provided in WO 99/06890 (Pappas et al.) that is incorporated by reference.

Once the various layers have been applied and dried on the substrate, the negative-working imageable elements can be enclosed in water-impermeable material that substantially inhibits the transfer of moisture to and from the element and “heat conditioned” as described in U.S. Pat. No. 7,175,969 (noted above).

The lithographic printing plate precursors can be stored and transported as stacks of precursors within suitable packaging and containers known in the art.

### Imaging Conditions

During use, the lithographic printing plate is exposed to a suitable source of exposing radiation depending upon the first and second infrared radiation absorbing cyanine dyes in the radiation-sensitive composition to provide specific sensitivity that is at a λₘₐₓ wavelength of at least 700 nm and up to and including 1400 nm, or at least 750 nm and up to and including 1250 nm.

For example, imaging can be carried out using imaging or exposing radiation from an infrared laser (or array of lasers) at a λₘₐₓ of at least 750 nm and up to and including about 1400 nm and typically at least 750 nm and up to and including 1250 nm. Imaging can be carried out using imaging radiation at multiple wavelengths at the same time if desired.

The laser used to expose the lithographic printing plate precursor is usually a diode laser, because of the reliability and low maintenance of diode laser systems, but other lasers such as gas or solid-state lasers can also be used. The combination of power, intensity and exposure time for laser imaging would be readily apparent to one skilled in the art. Presently, high performance lasers or laser diodes used in commercially available imagesetters emit infrared radiation at a wavelength of at least 800 nm and up to and including 850 nm or at least 1060 and up to and including 1120 nm.

The imaging apparatus can be configured as a flatbed recorder or as a drum recorder, with the lithographic printing plate precursor mounted to the interior or exterior cylindrical surface of the drum. An example of an useful imaging apparatus is available as models of Kodak® Trendsetter platesetters available from Eastman Kodak Company that contain laser diodes that emit near infrared radiation at a λₘₐₓ of about 830 nm. Other suitable imaging sources include the Crescent 42T Platesetter that operates at a wavelength of 1064 nm (available from Gerber Scientific, Chicago, Ill.) and the Screen PlateRite 4300 series or 8600 series platesetter (available from Screen USA, Chicago, Ill.).

Imaging with infrared radiation can be carried out generally at imaging energies of at least 30 mJ/cm² and up to and including 500 mJ/cm², and typically at least 50 mJ/cm² and up to and including 300 mJ/cm² depending upon the sensitivity of the imageable layer.

While laser imaging is most desired in the practice of this invention, thermal imaging can be provided by any other means that provides thermal energy in an imagewise fashion. For example, imaging can be accomplished using a thermoresistive head (thermal printing head) in what is known as “thermal printing”, described for example in U.S. Pat. No. 5,488,025 (Martin et al.). Thermal print heads are commercially available (for example, a Fujitsu Thermal Head FTP-040 MCS001 and TDK Thermal Head F415 HH7-1089).

### Development and Printing

The present invention provides color contrast in the imaged precursor by providing a difference in optical density between the exposed and non-exposed regions of the imageable layer. The different in OD should be at least 0.1 so the color contrast (“printout”) between imaged regions and background is easily observed.

With or without a post-exposure baking step after imaging and before development, the imaged lithographic printing plate precursors are developed “on-press” as described in more detail below. In most embodiments, a post-exposure baking step is omitted. On-press development avoids the use of alkaline developing solutions typically used in conventional processing apparatus. The imaged precursor is mounted onto a printing press wherein the unexposed regions in the imageable layer are removed by a suitable fountain solution, lithographic printing ink, or a combination of both, when the initial printed impressions are made. Typical ingredients of aqueous fountain solutions include pH buffers, desensitizing agents, surfactants and wetting agents, humectants, low boiling solvents, biocides, antifoaming agents, and sequestering agents. A representative example of a fountain solution is Varn Litho Etch 142W+Varn PAR (alcohol sub) (available from Yarn International, Addison, Ill.).

The fountain solution is taken up by the non-imaged regions, that is, the surface of the hydrophilic substrate revealed by the imaging and development steps, and ink is taken up by the imaged (non-removed) regions of the imaged layer. The ink is then transferred to a suitable receiving material (such as cloth, paper, metal, glass, or plastic) to provide a desired impression of the image thereon. If desired, an intermediate “blanket” roller can be used to transfer the ink from the imaged precursor to the receiving material. The imaged precursors can be cleaned between impressions, if desired, using conventional cleaning means.

The presence of the first infrared radiation absorbing compound, which also has absorbance in the visible region of the electromagnetic spectrum, allows for visual inspection of the lithographic printing plate at any time.

The present invention provides at least the following embodiments and combinations thereof, but other combinations of features are considered to be within the present invention as a skilled artisan would appreciate from the teaching of this disclosure:

1. A negative-working, on-press developable lithographic printing plate precursor comprising a substrate, and having thereon an infrared radiation-sensitive imageable layer comprising:

a free radically polymerizable component,

an initiator composition that provides free radicals upon irradiation by infrared radiation,

a polymeric binder,

one or more first infrared radiation absorbing cyanine dyes, each having two same or different heterocyclic groups that are connected to each other by a methine chain having at least 7 carbon atoms, and the methine chain comprises a substituent comprising at least one group represented by the following Structure (I):

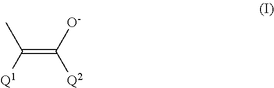

wherein Q¹ and Q² are hydrogen atoms or the same or different monovalent substituents, or Q¹ and Q² together provide carbon or heteroatoms to form a substituted or unsubstituted unsaturated ring, wherein the one or more first infrared radiation absorbing cyanine dyes are present in the infrared radiation-sensitive imageable layer in an amount of at least 2 weight %, based on the layer total solids, and

one or more second infrared radiation absorbing cyanine dyes that do not comprise a group represented by Structure (I).

2. The precursor of embodiment 1 wherein Structure (I) is further defined by Structure (Ia) or Structure (Ib):

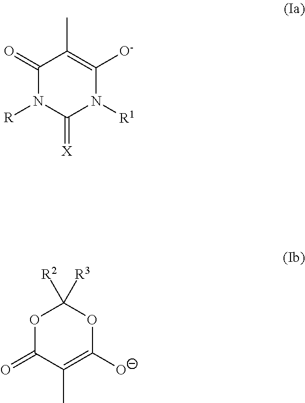

wherein X is an oxygen atom or sulfur atom, and R, R¹, R², and R³ are independently hydrogen, or substituted or unsubstituted alkyl, alkenyl, alkoxy, or phenyl groups.

3. The precursor of embodiment 1 or 2 wherein the molar ratio of the one or more first infrared radiation absorbing cyanine dyes to the one or more second infrared radiation absorbing cyanine dyes is at least 5:1 and to 1:2.

4. The precursor of any of embodiments 1 to 3 wherein the one or more first and one or more second infrared radiation absorbing cyanine dyes are present in the imageable layer independently in amounts of at least 2 weight % and up to and including 10 weight %.

5. The precursor of any of embodiments 1 to 4 wherein at least one of the one or more second infrared radiation absorbing cyanine dyes comprises one or more water-solubilizing groups.

6. The precursor of embodiment 5 wherein at least one of the one or more second infrared radiation absorbing cyanine dyes comprises one or more carboxy, sulfo, or phospho groups that are attached to one or more of the heterocyclic groups.

7. The precursor of any of embodiments 1 to 6 wherein upon irradiation at a wavelength of at least 700 nm and up to and including 1400 nm, provides a color change in the imageable layer of at least 0.1 ΔOD compared to the imageable layer before such irradiation.

8. The precursor of any of embodiments 1 to 7 wherein the initiator composition comprises an onium salt.

9. The precursor of any of embodiments 1 to 8 wherein the initiator composition comprises a diaryliodonium borate.

10. The precursor of embodiment 9 wherein the initiator composition comprises a diaryliodonium tetraaryl borate.

11. The precursor of any of embodiments 1 to 10 wherein the polymeric binder is a graft copolymer comprising a hydrophobic backbone to which are attached side chains comprising polyalkylene oxide segments, or the polymeric binder comprises a hydrophobic backbone to which are attached side chains comprising ethylenically unsaturated polymerizable groups, or the polymeric binder comprises a hydrophobic backbone to which are attached both side chains comprising polyalkylene oxide segments and side chains comprising ethylenically unsaturated polymerizable groups.

12. The precursor of any of embodiments 1 to 11 wherein the polymeric binder comprises a hydrophobic backbone to which are attached cyano groups.

13. The precursor of any of embodiments 1 to 12 wherein the infrared radiation-sensitive imageable layer is the outermost layer of the precursor.

14. A method for providing a lithographic printing plate, comprising:

imagewise exposing the negative-working, on-press developable lithographic printing plate precursor of any of embodiments 1 to 13 to infrared radiation to form exposed and non-exposed regions in the imaged imageable layer, and

without contact it with an alkaline processing solution, mounting the imaged imageable layer onto a printing press and removing the non-exposed regions of the imaged imageable layer using a lithographic printing ink, fountain solution, or both lithographic printing ink and fountain solution.

15. The method of embodiment 14 comprising imagewise exposing the negative-working, on-press developable lithographic printing plate precursor at a wavelength of at least 750 nm and up to and including 1250 nm.

16. The method of embodiment 14 or 15 wherein the ΔOD between the exposed and non-exposed regions in the imageable layer is at least 0.1.

17. The method of any of embodiments 14 to 16 wherein the ΔOD between the exposed and non-exposed regions in the imageable layer is at least 0.15.

The following Examples are provided to illustrate the practice of this invention and are not meant to be limiting in any manner.

### Silicate Substrate:

An electrochemically grained, sulfuric acid-anodized aluminum-containing support was immersed into a 4 weight % sodium silicate aqueous solution for 17 seconds at 60° C. This silicate-treated support was then washed with de-ionized water and dried at 100° C. for 60 seconds. The resulting substrate had an Rₐ value of 0.4 μm and an oxide weight of 2.7 g/m².

Polymer 1 is represented by the following formula:

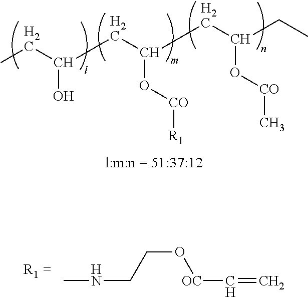

Polymer 2 is a 25% dispersion of a copolymer prepared from acrylonitrile/polyethylene glycol methyl ether methacrylate/styrene. Polymer 2 was prepared as follows: A solution of PEGMA (20 g) dissolved in a mixture of deionized water (74.8 g) and n-propanol (241.4 g), was charged into a 1000 ml four-necked flask, and was heated slowly to slight reflux (76° C.) under a nitrogen atmosphere. A pre-mixture of styrene (20 g), acrylonitrile (70 g), and Vazo-64 polymerization initiator (0.7 g) was added over a 2-hour period. Six hours later, another aliquot of Vazo-64 (0.5 g) was added. The temperature was raised to 80° C. Subsequently, two more aliquots of Vazo-64 (0.35 g each) were added over a period of 6 hours. After reaction for a total of 19 hours, the conversion to copolymer was >98% based on a determination of percent non-volatiles. The weight ratio of PEGMA/styrene/acrylonitrile was 10:20:70 and the n-propanol/water ratio was 76:24. The residual acrylonitrile in solution was 0.5 weight % based on determination by <1> H-NMR. Polymer 2 was used as a 25 weight % solution.

Borate A is represented by the following formula:

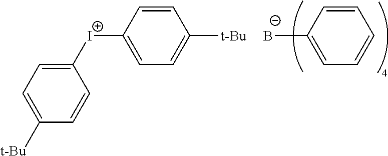

IR Dye A is represented by the following formula:

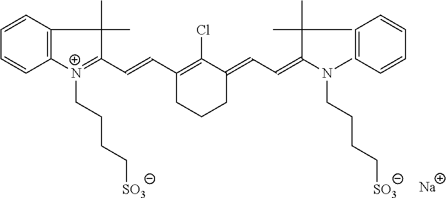

IR Dye B is represented by the following formula:

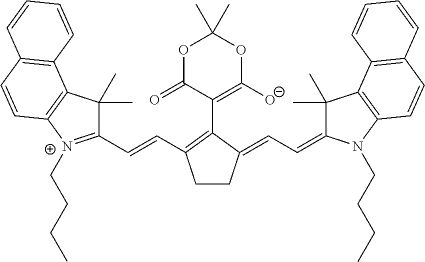 [SMILES: CCCCN1/C(=C/C=C2\CCC(/C=C/C3=[N+](CCCC)c4ccc5ccccc5c4C3(C)C)=C2C2=C([O-])OC(C)(C)OC2=O)C(C)(C)c2c1ccc1ccccc21]

IR Dye C is represented by the formula:

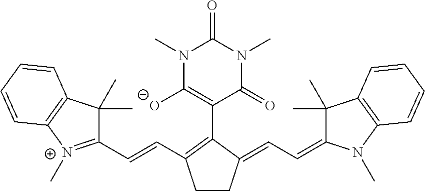 [SMILES: CN1/C(=C/C=C2\CCC(/C=C/C3=[N+](C)c4ccccc4C3(C)C)=C2c2c([O-])n(C)c(=O)n(C)c2=O)C(C)(C)c2ccccc21]

IR Dye D is represented by the formula:

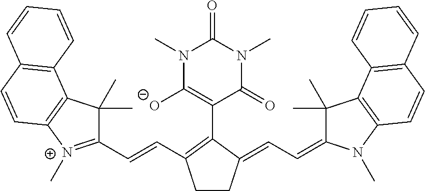 [SMILES: CN1/C(=C/C=C2\CCC(/C=C/C3=[N+](C)c4ccc5ccccc5c4C3(C)C)=C2c2c([O-])n(C)c(=O)n(C)c2=O)C(C)(C)c2c1ccc1ccccc21]

Oligomer A is an urethane acrylate in a 80 weight % solution of 2-butanone and is prepared by reacting DESMODUR® N100 (an aliphatic polyisocyanate resin based on hexamethylene diisocyanate from Bayer Corp., Milford, Conn.) with hydroxyethyl acrylate and pentaerythritol triacrylate.

Oligomer 2 is ethoxylated 4 pentaerythritol tetraacrylate that is available as SR-494 from Sartomer Japan (Yokohama, Japan).

DMAEMA represents N,N′-dimethyl aminoethyl methacrylate that is available from Tokyo Kasei (Tokyo, Japan)

Polymer 3 is poly(ethylene glycol diacetic acid) that is available from Sigma-Aldrich (Tokyo, Japan)

Phosmer PE has the following formula and is available from Uni-chemical (Japan):

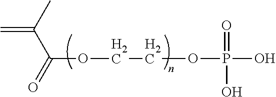

Byk® 337 is a modified dimethyl polysiloxane copolymer that is available from Byk Chemie (Wallingford, Conn.).

PGME is propyleneglycol monomethylester that is available from Tokyo kasei (Tokyo, Japan).

BLO represents γ-butyrolactone that is available from Tokyo kasei (Tokyo, Japan).

MEK represents methyl ethyl ketone that is available from Tokyo kasei (Tokyo, Japan).

Lithographic printing plate precursors to be evaluated were prepared using the Imageable Layer Formulation described below. The amounts of IR Dye A, IR Dye B, and Borate A are described in TABLE I below. Where the amounts of both IR dyes or of Borate A were different from that of the Imageable Layer Formulation, the amounts of all of the other components were adjusted by keeping their original ratio in the Image Layer Formulation. The Solvent Formulation was used as the solvent mixture for the Imageable Layer Formulation 1, and the non-volatile % (solids) in the coating formulation was set at 8%.

Imageable Layer Formulation

| Component | % Solids |
|---|---|
| Polymer 1 | 9.0 |
| Polymer 2 | 31.5 |
| Borate A | (9.0) |
| IR Dye A | (2.0) |
| IR Dye B | (1.0) |
| Oligomer A | 14.6 |
| Oligomer B | 10.6 |
| Phosmer PE | 9.0 |
| DMAEMA | 7.9 |
| Byk ® 337 | 0.9 |
| Polymer 3 | 4.5 |

Solvent Formulation

| Solvent | Weight % |
|---|---|
| 1-Propanol | 40.0 |
| PGME | 24.0 |
| BLO | 1.0 |
| MEK | 30.0 |
| Distilled Water | 5.0 |

The imageable layer radiation-sensitive compositions were prepared by mixing the Imageable Layer Formulation with the Solvent Formulation 2 and applying the resulting composition to the silicate-treated substrate described above using a #9 rod bar to provide a dry coating weight of 1.3 g/m². The applied composition was dried at 110° C. for 50 seconds.

The resulting lithographic printing plate precursors were imaged using a Kodak Magnus 800 imagesetter (Eastman Kodak Company) to evaluate the printout, IR speed (sensitivity), and press life. The range of the imaging power series was from 43 mJ/cm² to 215 mJ/cm². The resolution setting was 2400 dots per inch (945 dots per cm). A Gretag Macbeth X-rite528 (available from X-Rite Inc., Grand Rapids, Mich.) was used to evaluate the (delta) ΔOD value between the imaged region and non-imaged area (hereinafter printout or PO). To determine the IR speed of each lithographic printing plate precursor, a short press run test was done using the same power series imaged precursors. After 2,000 impressions in the press test, the IR speed was determined by measuring the magenta ink OD at a 1×1 checker flag imaging area and a 2×2 checker flag imaging area, and it was decided at the imaging power where the same OD was seen for both imaging areas.

For the press life evaluation, a Komori S-26 press machine (available from Komori Corporation, Tokyo, Japan) was used with an accelerated press life test condition. In this condition, it was said that it was desirable to print 10,000 copies with a good image.

The results are provided below in TABLE I.

TABLE I

| | First IR Dye | Second IR Dye | Borate A | | Imaging Speed | Press Life |
|---|---|---|---|---|---|---|
| Precursor | (% Solids) | (% Solids) | (% Solids) | Printout | (mJ/cm²) | (copies) |
| Invention | IR Dye C (2%) | IR Dye A (1%) | 9% | A | 107 | 20,000 |
| Example 1 | | | | | | |
| Invention | IR Dye C (3%) | IR Dye A (1%) | 9% | A | 129 | 20,000 |
| Example 2 | | | | | | |
| Invention | IR Dye D (2%) | IR Dye A (1%) | 9% | B | 107 | 20,000 |
| Example 3 | | | | | | |
| Invention | IR Dye D (3%) | IR Dye A (1%) | 9% | B | 129 | 20,000 |
| Example 4 | | | | | | |
| Invention | IR Dye C (2%) | IR Dye A (1%) | 11% | A | 107 | 20,000 |
| Example 5 | | | | | | |
| Invention | IR Dye C (2%) | IR Dye A (1%) | 14% | A | 129 | 20,000 |
| Example 6 | | | | | | |
| Invention | IR Dye B (3%) | IR Dye A (1%) | 9% | A | 129 | 20,000 |
| Example 7 | | | | | | |
| Comparative | IR Dye C (1%) | IR Dye A (1%) | 9% | C | 215< | 6,000 |
| Example 1 | | | | | | |
| Comparative | IR Dye C 2% | N.A. | 9% | A | 161 | 8,000 |
| Example 2 | | | | | | |
| Comparative | IR Dye D (1%) | IR Dye A (1%) | 9% | D | 215< | 5,000 |
| Example 3 | | | | | | |
| Comparative | IR Dye D 2% | N.A. | 9% | B | 161 | 7,000 |
| Example 4 | | | | | | |
| Comparative | IR Dye B (3%) | N.A. | 9% | A | 161 | 10,000 |
| Example 5 | | | | | | |
| Comparative | N.A. | IR Dye A (1%) | 9% | E | 129 | 18,000 |
| Example 6 | | | | | | |

PO evaluation of A (excellent) to E (no printout)
N.A. = not applicable

All of the Invention Example precursors exhibited acceptable press life with good printout and good imaging speed. When the amount of the first IR Dye was below 2 weight % (for example, Comparative Examples 1, 3, and 6), the degree of printout was too low for acceptability. On the other hand, when the second IR Dye was absent (Comparative Examples 2, 4, and 5), slower IR speed and poorer press life were observed.

The invention has been described in detail with particular reference to certain preferred embodiments thereof, but it will be understood that variations and modifications can be effected within the spirit and scope of the invention.

1. A negative-working, on-press developable lithographic printing plate precursor comprising a substrate, and having thereon an infrared radiation-sensitive imageable layer comprising:
a free radically polymerizable component,
an initiator composition that provides free radicals upon irradiation by infrared radiation,
a polymeric binder,
one or more first infrared radiation absorbing cyanine dyes, each having two same or different heterocyclic groups that are connected to each other by a methine chain having at least 7 carbon atoms, and the methine chain comprises a substituent comprising at least one group represented by the following Structure (I): 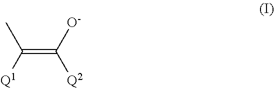
wherein Q¹ and Q² are hydrogen atoms or the same or different monovalent substituents, or Q¹ and Q² together provide carbon or heteroatoms to form a substituted or unsubstituted unsaturated ring, wherein the one or more first infrared radiation absorbing cyanine dyes are present in the infrared radiation-sensitive imageable layer in an amount of at least 2 weight %, based on the layer total solids, and
one or more second infrared radiation absorbing cyanine dyes that do not comprise a group represented by Structure (I).

2. The precursor of claim 1 wherein Structure (I) is further defined by Structure (Ia) or Structure (Ib): 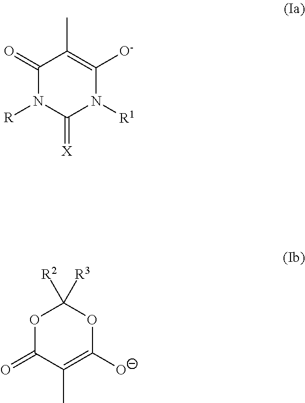
wherein X is an oxygen atom or sulfur atom, and R, R¹, R², and R³ are independently hydrogen, or substituted or unsubstituted alkyl, alkenyl, alkoxy, or phenyl groups.

3. The precursor of claim 1 wherein the molar ratio of the one or more first infrared radiation absorbing cyanine dyes to the one or more second infrared radiation absorbing cyanine dyes is at least 5:1 and to 1:2.

4. The precursor of claim 1 wherein the one or more first and one or more second infrared radiation absorbing cyanine dyes are present in the imageable layer independently in amounts of at least 2 weight % and up to and including 10 weight %.

5. The precursor of claim 1 wherein at least one of the one or more second infrared radiation absorbing cyanine dyes comprises one or more water-solubilizing groups.

6. The precursor of claim 5 wherein at least one of the one or more second infrared radiation absorbing cyanine dyes comprises one or more carboxy, sulfo, or phospho groups that are attached to one or more of the heterocyclic groups.

7. The precursor of claim 1 wherein upon irradiation at a wavelength of at least 700 nm and up to and including 1400 nm, provides a color change in the imageable layer of at least 0.1 ΔOD compared to the imageable layer before such irradiation.

8. The precursor of claim 1 wherein the initiator composition comprises an onium salt.

9. The precursor of claim 1 wherein the initiator composition comprises a diaryliodonium borate.

10. The precursor of claim 9 wherein the initiator composition comprises a diaryliodonium tetraaryl borate.

11. The precursor of claim 1 wherein the polymeric binder is a graft copolymer comprising a hydrophobic backbone to which are attached side chains comprising polyalkylene oxide segments, or the polymeric binder comprises a hydrophobic backbone to which are attached side chains comprising ethylenically unsaturated polymerizable groups, or the polymeric binder comprises a hydrophobic backbone to which are attached both side chains comprising polyalkylene oxide segments and side chains comprising ethylenically unsaturated polymerizable groups.

12. The precursor of claim 1 wherein the polymeric binder comprises a hydrophobic backbone to which are attached cyano groups.

13. The precursor of claim 1 wherein the infrared radiation-sensitive imageable layer is the outermost layer of the precursor.

14. The precursor of claim 1 wherein:
Structure (I) of the one or more first infrared radiation absorbing cyanine dyes is further defined by Structure (Ia) or Structure (Ib): 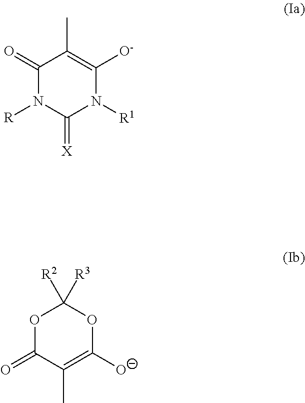
wherein X is an oxygen atom or sulfur atom, and R, R¹, R², and R³ are independently hydrogen, or substituted or unsubstituted alkyl, alkenyl, alkoxy, or phenyl groups,
the molar ratio of the first infrared radiation absorbing cyanine dye to the second infrared radiation absorbing cyanine dye is at least 5:1 and to 1:2,
the first and second infrared radiation absorbing cyanine dyes are present in the imageable layer independently in amounts of at least 2 weight % and up to and including 10 weight %,
at least one of the one or more second infrared radiation absorbing cyanine dyes comprises one or more carboxy, sulfo, or phospho groups that are attached to one or more of the heterocyclic groups,
upon irradiation at a wavelength of at least 700 nm and up to and including 1400 nm, provides a color change in the imageable layer of at least 0.15 ΔOD compared to the imageable layer before such irradiation,
the initiator composition comprises a diaryliodonium tetraaryl borate, and
the polymeric binder is a graft copolymer comprising a hydrophobic backbone to which are attached side chains comprising polyalkylene oxide segments, or the polymeric binder comprises a hydrophobic backbone to which are attached side chains comprising ethylenically unsaturated polymerizable groups, or the polymeric binder comprises a hydrophobic backbone to which are attached both side chains comprising polyalkylene oxide segments and side chains comprising ethylenically unsaturated polymerizable groups.

15. A method for providing a lithographic printing plate, comprising:
imagewise exposing the negative-working, on-press developable lithographic printing plate precursor of claim 1 to infrared radiation to form exposed and non-exposed regions in the imaged imageable layer, and
without contacting it with an alkaline processing solution, mounting the imaged imageable layer onto a printing press and removing the non-exposed regions of the imaged imageable layer using a lithographic printing ink, fountain solution, or both lithographic printing ink and fountain solution.

16. The method of claim 15 comprising imagewise exposing the negative-working, on-press developable lithographic printing plate precursor at a wavelength of at least 750 nm and up to and including 1250 nm.

17. The method of claim 15 wherein the ΔOD between the exposed and non-exposed regions in the imageable layer is at least 0.1.

18. The method of claim 15 wherein the ΔOD between the exposed and non-exposed regions in the imageable layer is at least 0.15.

19. A method for providing a lithographic printing plate, comprising:
imagewise exposing the negative-working, on-press developable lithographic printing plate precursor of claim 14 to infrared radiation to form exposed and non-exposed regions in the imaged imageable layer, wherein the ΔOD between the exposed and non-exposed regions is at least 0.15, and
without contacting it with an alkaline processing solution, mounting the imaged imageable layer onto a printing press and removing the non-exposed regions of the imaged imageable layer using a lithographic printing ink, fountain solution, or both lithographic printing ink and fountain solution.
